(19) United States
(12) Patent Application Publication
(10) Pub. No.: US 2001/0018275 A1
(43) Pub. Date: Aug. 30, 2001

(54) Method of using SACVD deposition and corresponding deposition reactor

(76) Inventor: Michele Vulpio, Santo Spirito (BA) (IT)

Correspondence Address: FLEIT, KAIN, GIBBONS,, GUTMAN & BONGINI, P.L., ONE BOCA COMMERCE CENTER, 551 NORTHWEST 77TH STREET, SUITE 111, BOCA RATON, FL, 33487, US

(21) Appl. No.: 09/794,299

(22) Filed: Feb. 27, 2001

(30) Foreign Application Priority Data
Feb. 29, 2000 (EP) 00830163.3

(51) Int. Cl. H01L 21/31; H01L 21/469

(52) U.S. Cl. 438/789; 438/788

(57) ABSTRACT

A method is provided for using SACVD deposition to deposit at least one layer of dielectric material inside a deposition reactor. According to the method, a stream of a remote plasma of a reaction gas is supplied into the reactor, and microwaves are applied inside a gas feed conduit of the reactor in order to produce sufficient radicals of the reaction gas to initiate a deposition reaction. Also provided is a deposition reactor for performing an SACVD deposition technique for fabricating a semiconductor integrated circuit. The reactor includes a reaction chamber, a heater for heating the chamber, at least one reaction gas feed conduit, and a magnetron device. The reaction gas feed conduit supplies a reaction gas to the interior of the chamber, and the magnetron device produces sufficient radicals of the reaction gas within the chamber to initiate a deposition reaction.

### BACKGROUND OF THE INVENTION

1. Field of the Invention

The present invention relates to integrated circuits, and more specifically to a Sub-Atmospheric Chemical Vapor Deposition (SACVD) application method for fabricating semiconductor integrated circuits and a corresponding deposition reactor.

2. Description of Related Art

Providing adjacent or overlapping dielectric material layers having the same composition is fairly common in today's electronic technologies, and at various stages of manufacturing integrated circuits. In order to form two-stack layers of this kind, it is standard practice to have a first layer of dielectric material partly or fully overlapped by a second dielectric layer. However, before forming the second layer, there can be intermediate process phases leading to the formation of a sacrificial layer which is then in part or fully removed. In any event, at the end of these process phases, the second dielectric layer will have its bottom surface directly in contact with the top surface of the first dielectric layer.

Dielectric materials, such as silicon oxide or nitride, are usually used either to provide electrical isolation between conductive layers or to protect underlying integrated circuit structures from contamination. A basic aim of two-stack dielectric layers is to ensure protection in the event that one of the layers becomes damaged. Therefore, it is important that in no portion of the two-stack layer is there left a doubtful adhesion between the overlapping layers.

Nevertheless, some materials have adhesion problems at the interface. These problems may originate from inherent characteristics of the material that are not yet fully understood by the experts. For example, it is believed that because of different thicknesses of the layers, stress situations which tend to delaminate the material can occur when such strain exceeds the molecular attraction force between the layers. Contributing factors may be the total of the processing steps undergone by the semiconductor, or different processing temperatures. In addition, proper adhesion between the overlapping layers is difficult to achieve because of certain processing methods that are customarily used during the fabrication of integrated circuits.

Conventionally, the dielectric layers (except for the first one which can be formed by thermal oxidation) are usually formed by deposition techniques such as CVD (Chemical Vapor Deposition) performed inside a reactor. The chemical precursor of the element to be deposited is reacted during the gas phase. The chemio-physical properties of the layer are controlled by such processing parameters as pressure and the concentration of reactive gases like O₃ and TEOS (TetraEthylOrthoSilicate). However, the dielectric formed with the CVD method is often uneven through its thickness due to a sort of reactive inertia at the initial phase of the deposition. Furthermore, any residues left from previous processing phases on the surface of the first layer may interfere with the deposition and proper adhesion between the layers, especially when the dielectric materials happen to be markedly stiff (as is the case with silicon nitride and oxynitride).

Aimed at improving the adhesion between dielectric material layers, certain techniques have been developed in which the surface of the underlying layer is treated before forming the second layer. For example, a sputtering process phase of ion bombarding the surface of the first layer may be carried out to enhance adhesion of the reactants to be deposited. This is done, for example, with layers of silicon oxide deposited using TEOS as precursor.

Another viable approach is known as Sub-Atmospheric Chemical Vapor Deposition (SACVD), which consists of depositing a doped or undoped film of silicon oxide based on the combustive reaction of O₂ and TEOS initiated by the presence of ozone (O₃). Details of this technique can be found in K. Fujino et al., “Doped Silicon Oxide Deposition by Atmospheric Pressure and Low Temperature Chemical Vapor Deposition Using Tetraethoxysilane and Ozone,” Journal of the Electrochemical Society, Vol. 138, No. 10, October 1991, Manchester, New Hampshire, U.S.A., pp. 3019-3024, which is herein incorporated by reference.

The peculiar feature of this deposition technique is a good gap-fill and excellent step coverage, which can be achieved by optimizing the deposition parameters. It has, however, a major limitation in its low throughput of no more than 6.5 wafers/hour. Furthermore, the use of ozone (O₃) has several drawbacks: (1) it is a highly harmful gas; (2) the proportion of ozone is dictated by the limitations of the ozonizer power output; and (3) the TEOS flow cannot be increased to achieve a higher throughput without at the same time losing gap-fill. At process temperature, ozone undergoes almost complete dissociation already inside the reactive gas injection system (shawer head) into O₂ and O radicals which constitute radical initiators activating the combustion process.

It is known, from literature as well as from tests carried out by the Inventor, that the gap filling rate of the dielectric film improves with increased pressure and ozone proportion, and decreased TEOS flow rate. Unfortunately, equipment throughput proceeds in the reverse direction. Accordingly, raising the flow rate of TEOS while keeping the ozone ratio unaltered (for maximum gap filling performance) appears to be the most convenient course for getting a higher process capacity. However, this ideal setting has a limitation in the ability to maximize the ozone percentage with the ozonizers currently in use. These ozonizers can supply 17% ozone at most.

### SUMMARY OF THE INVENTION

In view of these drawbacks, it is an object of the present invention to overcome the above-mentioned drawbacks and to provide a method of using SACVD deposition that improves the yield in the deposition of dielectric layers while providing good step coverage.

Another object of the present invention is to provide a deposition method in which a remote oxygen (O₂) plasma is used to generate the oxygen radicals necessary for initiating a combustion process without using ozone. In preferred embodiments, the oxygen radicals are directly produced by a magnetron that is associated with the deposition reactor and capable of providing maximum scattering of the molecules introduced into the reaction chamber.

One embodiment of the present invention provides a method of using SACVD deposition to deposit at least one layer of dielectric material inside a deposition reactor during the fabrication of at least one semiconductor integrated circuit. According to the method, a stream of a remote plasma of a reaction gas is supplied into the reactor, and microwaves are applied inside a gas feed conduit of the reactor in order to produce sufficient radicals of the reaction gas to initiate a deposition reaction. In a preferred embodiment, the reaction gas is oxygen.

Another embodiment of the present invention provides a deposition reactor for performing an SACVD deposition technique for fabricating a semiconductor integrated circuit. The reactor includes a reaction chamber, a heater for heating the chamber, at least one reaction gas feed conduit, and a magnetron device. The reaction gas feed conduit supplies a reaction gas to the interior of the chamber, and the magnetron device produces sufficient radicals of the reaction gas within the chamber to initiate a deposition reaction. In one preferred embodiment, the reactor also includes a gas feed pump for forcing the reaction gas into the chamber.

Other objects, features, and advantages of the present invention will become apparent from the following detailed description. It should be understood, however, that the detailed description and specific examples, while indicating preferred embodiments of the present invention, are given by way of illustration only and various modifications may naturally be performed without deviating from the present invention.

### BRIEF DESCRIPTION OF THE DRAWINGS

FIG. 1 shows a process reactor in which a conventional SACVD deposition process is carried out; and

FIG. 2 shows a modified process reactor that can be used to carry out an SACVD deposition process according to a preferred embodiment of the present invention.

### DETAILED DESCRIPTION OF PREFERRED EMBODIMENTS

Preferred embodiments of the present invention will be described in detail hereinbelow with reference to the attached drawings.

In general, preferred embodiments of the present invention are directed to methods for fabricating monolithically integrated electronic circuits having at least one dielectric material layer. The following description covers deposition aspects of overlapping dielectric layers in detail for the convenience of illustration only.

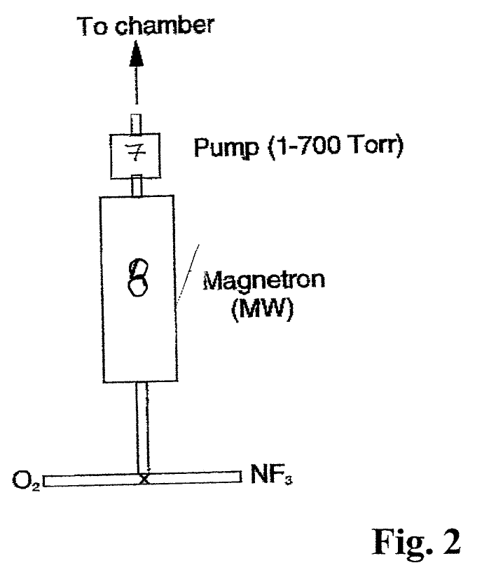

FIG. 2 shows a process reactor for fabricating electronic circuits integrated on a semiconductor. The process reactor 1 can be used to carry out SACVD deposition operations in accordance with a preferred embodiment of the present invention. The reactor 1 is constructed similar to conventional reactors, but has been modified to allow the SACVD deposition method of the present invention to be implemented. This reactor has a reaction chamber 2, which basically includes a quartz tube, that receives or is injected by components of the reaction which leads to the formation of deposited layers of dielectric material on the semiconductor.

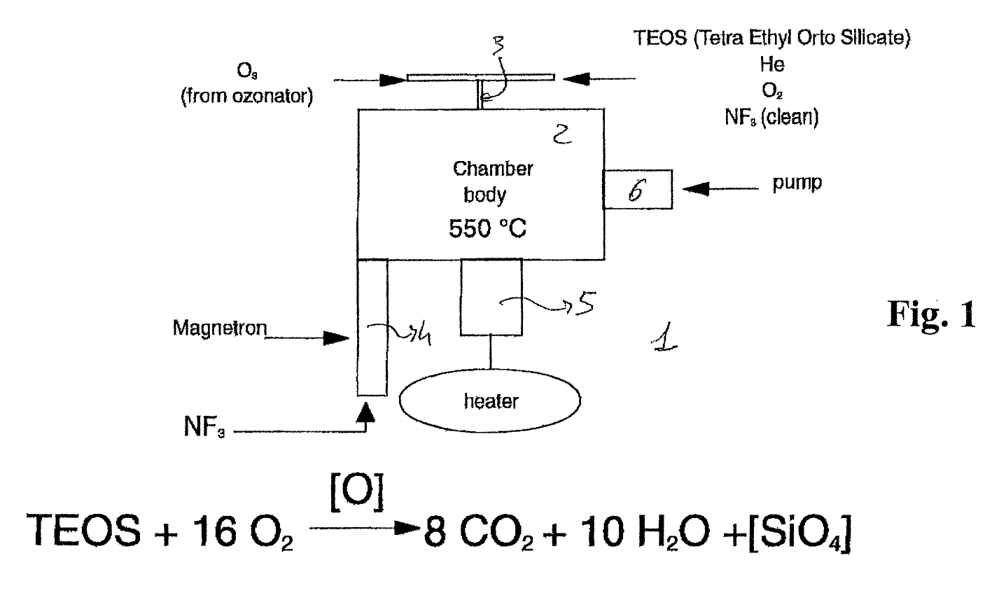

The reaction chamber 2 is provided with an opening for introducing the semiconductor wafers to be reacted, and for subsequently taking them out. A gas feed conduit 3 leads to the interior of the reaction chamber 2 for feeding the chamber interior with gas phase reactants. This feed conduit 3 branches off outside the chamber 2 to receive separate gas streams from respective sources (not shown). The reaction chamber 2 has a magnetron device 4 associated therewith which emits electromagnetic waves into the chamber for the purpose of scattering the gas molecules therein, in accordance with the present invention. In the conventional design of FIG. 1, the magnetron is only provided to dissociate the NF₃ gas for cleaning.

The reaction chamber 2 also includes a heater 5 for raising its internal temperature to a predetermined fixed value for the chemical reaction to take place. Advantageously in preferred embodiments of the present invention, a pump 6 for adjusting the process pressure is associated with the reaction chamber 2, and an additional pump 7 is provided on the process gas feed conduit 3 (for the purpose explained below). The additional pump 7 may be a rotor pump. Also, a magnetron 8 is mounted on the conduit 3 upstream of the pump 7.

A deposition method according to a preferred embodiment of the present invention will now be described in detail. During the SACVD process which by deposition leads to the formation of layers of dielectric material on semiconductor, a stream of oxygen (O₂) plasma generated within the magnetron is fed into the reaction chamber 2 through the feed conduit 3. The magnetron device is operated to scatter the oxygen molecules as much as possible, thereby enabling free oxygen (O) radicals to be released onto the substrate, without exposing it to the plasma action.

By adjusting the magnetron action, a proportion of oxygen (O) radicals can be produced in a wide range of concentrations (ideally 0 to 98%). This is especially important to an optimum gap filling of the dielectric material layer being formed, even at other than the standard TEOS flow rate. Further, this allows the throughput of the reactor 1 to be increased with no tradeoffs in the properties of the general SACVD deposition technique. An essential feature of the method according to the preferred embodiment of the present invention is that ozone (O₃) is not used as a process gas.

One difference between conventional reactors and the reactor 1 used in this embodiment of the present invention is that the magnetron 4 is additionally provided with an oxygen line. Further, the impedance adapter (matching network) connected thereto is made to suit the discharge of nitrogen trifluoride (NF₃) and oxygen (O₂).

In one practical embodiment, the pressure value at which the plasma discharge is activated in the magnetron is 1.5 Torr. The process pressure is near-ambient and approximately equal to 700 Torr. Consequently, forcing the gas stream, which contains the oxygen (0) radicals at a low pressure, into a high-pressure reactor could pose a problem. In the preferred embodiment, this problem is obviated by the provision of a pump 7 (e.g., a rotor pump) between the magnetron 8 and the chamber 2. In practical terms, such an additional pump is definitely less expensive than the ozonizer of the conventional apparatus. The rotor pump 7 may be calibrated for operating in the 1 to 100 Torr range. To prevent corrosion problems with the pump from the oxygen (O) radicals, the pump may be kept lubricated with suitable lubricants (e.g., a polyfluorinated oil such as Fomblin).

The method and the reactor of the present invention solve the drawbacks of having as reactive gas the ozone in limited concentration, and offer a number of advantages. For example, they make possible an SACVD deposition with good gap-fill and step coverage, while providing a significantly higher throughput than current systems.

While there has been illustrated and described what are presently considered to be the preferred embodiments of the present invention, it will be understood by those skilled in the art that various other modifications may be made, and equivalents may be substituted, without departing from the true scope of the present invention. Additionally, many modifications may be made to adapt a particular situation to the teachings of the present invention without departing from the central inventive concept described herein. Furthermore, an embodiment of the present invention may not include all of the features described above. Therefore, it is intended that the present invention not be limited to the particular embodiments disclosed, but that the invention include all embodiments falling within the scope of the appended claims.

What is claimed is:

1. A method of using SACVD deposition to deposit at least one layer of dielectric material inside a deposition reactor during the fabrication of at least one semiconductor integrated circuit, said method comprising the steps of:
supplying a stream of a remote plasma of a reaction gas into the reactor; and
applying microwaves inside a gas feed conduit of the reactor in order to produce sufficient radicals of the reaction gas to initiate a deposition reaction.

2. The method as defined in claim 1, wherein the reaction gas is oxygen.

3. The method as defined in claim 1, wherein the microwave activation pressure is 1.5 Torr.

4. The method as defined in claim 1, wherein in the supplying step, the stream of the remote plasma of the reaction gas is forced into the reactor.

5. The method as defined in claim 1, wherein the reaction pressure is within the range of 1 to 700 Torr.

6. A deposition reactor for performing SACVD deposition to deposit at least one layer of dielectric material during the fabrication of at least one semiconductor integrated circuit, said reactor comprising:
a gas feed conduit for supplying a stream of a remote plasma of a reaction gas into the reactor; and
means for applying microwaves inside the gas feed conduit of the reactor in order to produce sufficient radicals of the reaction gas to initiate a deposition reaction.

7. The reactor as defined in claim 6, wherein the gas feed conduit supplies a stream of a remote plasma of oxygen into the reactor.

8. The reactor as defined in claim 6, wherein the microwave activation pressure is 1.5 Torr.

9. The reactor as defined in claim 6, further comprising means for forcing the stream of the remote plasma of the reaction gas into the reactor.

10. The reactor as defined in claim 6, wherein the reaction pressure is within the range of 1 to 700 Torr.

11. A deposition reactor for performing an SACVD deposition technique for fabricating a semiconductor integrated circuit, said reactor comprising:
a reaction chamber;
a heater for heating the chamber;
at least one reaction gas feed conduit for supplying a reaction gas to the interior of the chamber; and
a magnetron device on the feed conduit for producing sufficient radicals of the reaction gas within the chamber to initiate a deposition reaction.

12. The reactor as defined in claim 11, further comprising a gas feed pump on the conduit for forcing the reaction gas into the chamber.

13. The reactor as defined in claim 12, wherein the gas feed pump is located downstream of the magnetron device.

14. The reactor as defined in claim 11, wherein the reaction gas is oxygen.

15. The reactor as defined in claim 11, wherein the microwave activation pressure is 1.5 Torr.

16. The reactor as defined in claim 11, wherein the reactor produces a reaction pressure within the range of 1 to 700 Torr.
